(19) United States
(12) Patent Application Publication
(10) Pub. No.: US 2018/0231599 A1
(43) Pub. Date: Aug. 16, 2018

(54) ADAPTOR PLUG ASSEMBLY

(71) Applicant: Huang-Liang Wang, Taipei City (TW)

(72) Inventor: Huang-Liang Wang, Taipei City (TW)

(21) Appl. No.: 15/678,113

(22) Filed: Aug. 16, 2017

(30) Foreign Application Priority Data
Feb. 15, 2017 (TW) 106202197

(51) Int. Cl. G01R 31/04; H01R 13/66; H01R 31/06

(52) U.S. Cl. CPC G01R 31/04; H01R 31/065; H01R 13/6691; H01R 13/6683

(57) ABSTRACT

An adaptor plug assembly includes an adaptor plug and a mobile device which has a receiving unit. The adaptor plug includes a housing having a first connection end from which two terminals extends, and a second connection end in which three receptacle holes are defined. The two terminals are connected to the second connection end. A coil is mounted to one of the two terminals and electrically connected to a micro controller which includes a calculating unit, a transforming unit and a wire-less transmitting unit. The transforming unit receives current inducted by the coil and transforms the current into a first signal which is sent to and calculated by the calculating unit to be a second signal which is transmitted by the wire-less transmitting unit to the receiving unit of the mobile device. A power unit is installed in the housing provides power to the micro controller.

### BACKGROUND OF THE INVENTION

### 1. Fields of the Invention

The present invention relates to an adaptor plug assembly, and more particularly, to an adaptor plug assembly for being connected between an electronic device and the wall socket, and for providing information of operation of the electronic device and the status of power supply.

### 2. Descriptions of Related Art

The plugs of electronic devices some include two terminals and some include three terminals. The wall jacks some provide two receptacle holes and some provide three receptacle holes. In order to allow the users from different countries to connect their electronic devices to the wall jacks, the adaptor plug is developed which provides convenience for users to use different types of plugs to plug in the wall jackets to get electric current to their electronic devices or the like. Coils are needed to transfer the electric current between the electronic devices and the jackets. However, the conventional adaptor plugs cannot provide sufficient information about the electrical power connected to the electronic devices. Once the users find out abnormal situation, it is too late to separate the electronic devices from the adapter plugs.

The present invention intends to provide an adaptor plug which allows the users to be acknowledged the current supplied to the electronic devices.

### SUMMARY OF THE INVENTION

The present invention relates to an adaptor plug assembly for being connected between an electronic device and a wall socket. The adaptor plug assembly comprises an adaptor plug and a mobile device which has a receiving unit. The adaptor plug comprises a housing which includes a first connection end and a second connection end. Two terminals each have the first end thereof extending through the first connection end, and the second end of each of the two terminals is connected to the second connection end. A coil is mounted to one of the two terminals and electrically connected to a micro controller. The micro controller comprises a calculating unit, a transforming unit and a wire-less transmitting unit. The transforming unit receives current inducted by the coil, and transforms the current into a first signal which is sent to the calculating unit. The calculating unit calculates the first signal and obtains a second signal. The wire-less transmitting unit transmits the second signal to the receiving unit of the mobile device. A power unit is installed in the housing and electrically connected to the micro controller. The power unit provides power to the micro controller, such that a user is able to monitor the electrical connection between the wall socket and electronic device by the mobile device.

Preferably, the micro controller includes an overload protection unit which checks the inducted current of the coil and depresses voltage to protect the micro controller when the overload current is detected.

Preferably, the power unit is chargeable batteries. When the terminals on the first connection end are plugged to the wall socket, the power unit is charged. When the electronic device is connected to the second connection end, the power unit outputs power to the micro controller.

Preferably, the terminals each are a rod or a plate. The second connection end includes three receptacle holes. The two respective second ends of the two terminals are connected to two of the three receptacle holes, and the other one of the three receptacle holes has an earth terminal located therein.

Preferably, the transmitting method between the wire-less transmitting unit of the micro controller and the receiving unit of the mobile device is made by way of low-power Bluetooth transmission, cloud-transmission or ultra-red transmission.

The primary object of the present invention is to provide an adaptor plug assembly which allows the user to check the electrical connection between the electronic device and the wall socket by using a mobile device so as to avoid overload or any abnormal situation.

The present invention will become more apparent from the following description when taken in connection with the accompanying drawings which show, for purposes of illustration only, a preferred embodiment in accordance with the present invention.

### BRIEF DESCRIPTION OF THE DRAWINGS

FIG. 1 is a perspective view to show the adaptor plug of the present invention;

FIG. 2 shows the composition of the adaptor plug of the present invention;

FIG. 3 shows that the adaptor plug of the present invention is electrically connected between the wall socket and an electronic device;

FIG. 4 shows the wire-less transmission between the adaptor plug assembly of the present invention and the mobile device, and

FIG. 5 shows the mobile device displays the second signal.

### DETAILED DESCRIPTION OF THE PREFERRED NT

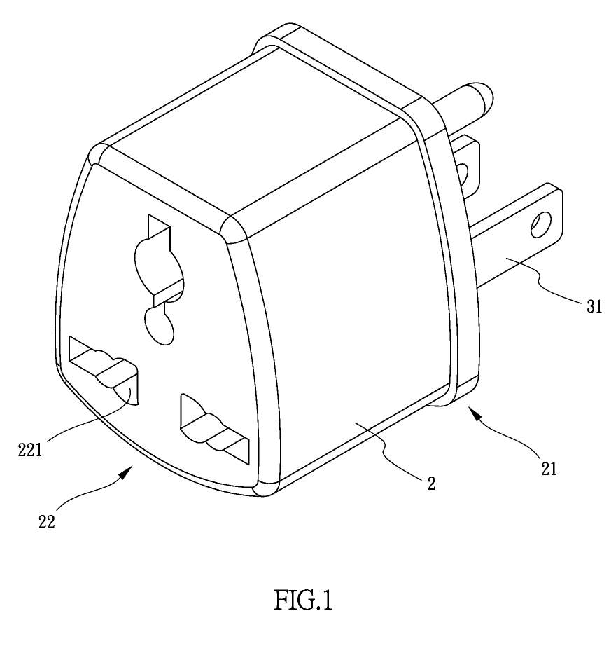

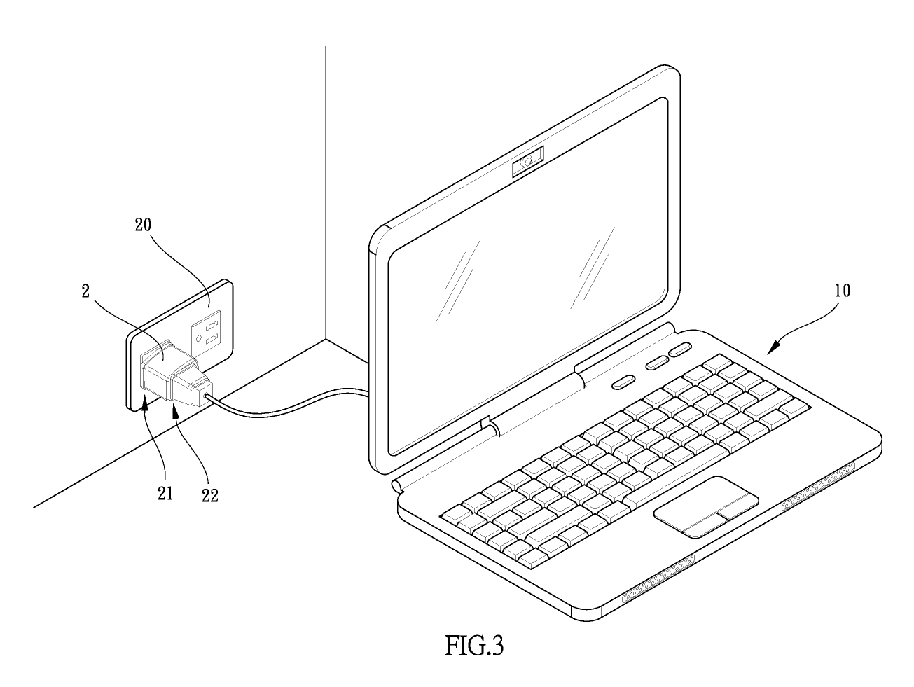

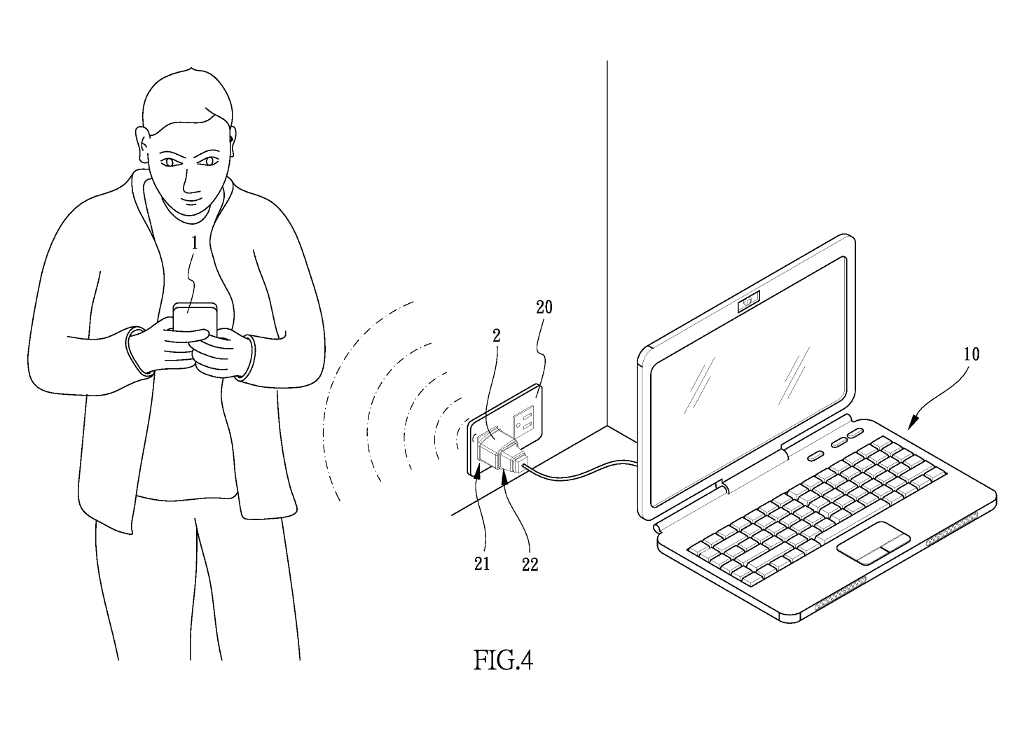

Referring to FIGS. 1 to 5, the adaptor plug assembly of the present invention for being connected between an electronic device 10 and a wall socket 20, comprises an adaptor plug and a mobile device 1 which has a receiving unit 11. The adaptor plug comprises a housing 2 which includes a first connection end 21 and a second connection end 22. Two terminals 31 each have the first end thereof extending through the first connection end 21, and the second end of each of the two terminals 31 is connected to the second connection end 22. The terminals 31 each are a rod or a plate. The second connection end 22 includes three receptacle holes 221. The two respective second ends of the two terminals 31 are connected to two of the three receptacle holes 221, and the other one of the three receptacle holes 221 has an earth terminal 222 located therein. It is noted that there can be three terminals 31 on the first connection end 21, and two receptacle holes 221 in the second connection end 22.

A coil 32 is mounted to one of the two terminals 31 and electrically connected to a micro controller 33. The micro controller 33 comprises a calculating unit 4, a transforming unit 5 and a wire-less transmitting unit 6. The transforming unit 5 receives current inducted by the coil 32, and transforms the current into a first signal 7 which is sent to the calculating unit 4. The calculating unit 4 calculates the first signal 7 and obtains a second signal 8. The wireless transmitting unit 6 transmits the second signal 8 to the receiving unit 11 of the mobile device 1. A power unit 9 is installed in the housing 2 and electrically connected to the micro controller 33. The power unit 9 provides power to the micro controller 33, such that a user is able to monitor the electrical connection between the wall socket 20 and electronic device 10 by the mobile device 1.

Preferably, the micro controller 33 includes an overload protection unit 331 which checks the inducted current of the coil 32 and depresses voltage to protect the micro controller 33 when the overload current is detected.

In this embodiment, the power unit 9 is chargeable batteries. When the terminals 31 on the first connection end 21 are plugged to the wall socket 20, the power unit 9 is charged. When the electronic device 10 is connected to the second connection end 22, the power unit 9 outputs power to the micro controller 33.

Preferably, the transmitting method between the wire-less transmitting unit 6 of the micro controller 33 and the receiving unit 11 of the mobile device 1 is made by way of low-power Bluetooth transmission, cloud-transmission or ultra-red transmission.

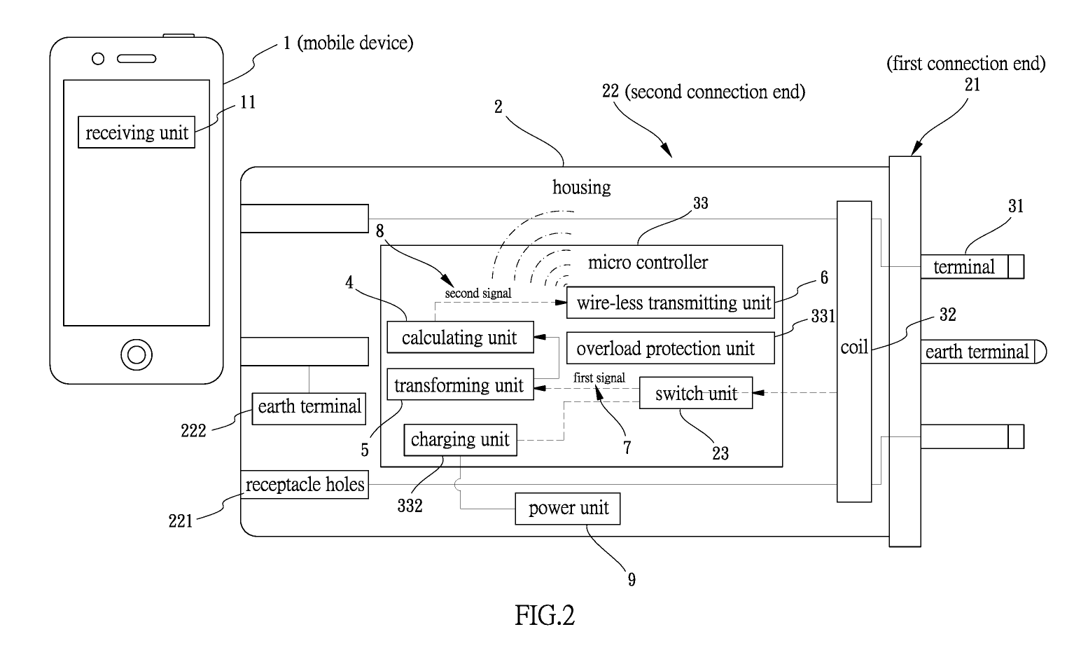

As disclosed in FIG. 2, taken the three terminals 31 and the three receptacle holes 221 as an example, the micro controller 33 has a charging unit 332 built therein. The charging unit 332 is electrically connected to the power unit 9 and the coil 32. The charging unit 332 collects electric power when the coil 32 proceeds electro-magnetic induction. The electric power is then sent to and charges the power unit 9. Furthermore, the micro controller 33 further has a switch unit 23 built therein which has one end thereof electrically connected to the coil 32, and the other end of the switch unit 23 is electrically connected to the charging unit 332 and the transferring unit 5. By operating the switch unit 23, the coil 32 can be either electrically connected to the charging unit 332 or the transferring unit 5. When the coil 32 is electrically connected to the charging unit 332, the charging mold is formed, and when the coil 32 is electrically connected to the transferring unit 5, the normal power-supply mold is formed. The micro controller 33 switch the two different molds via the switch unit 23.

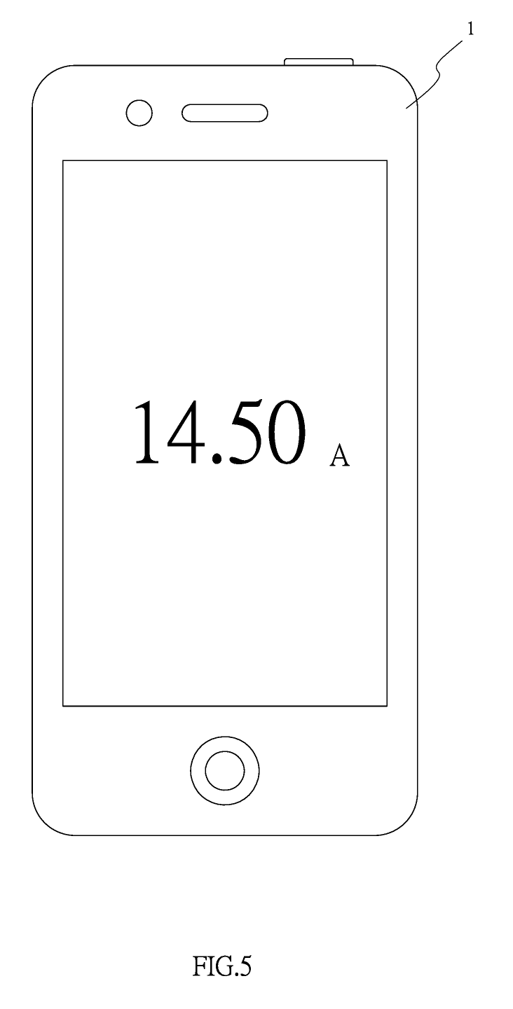

When the city power is not stable, the overload protection unit 331 of the micro controller 33 constantly checks the inducted current made by the coil 32 and depresses voltage to protect the micro controller 33 when the overload current is detected. The user is acknowledged the status by using the receiving unit 11 of the mobile device 1 to receive the latest information from the wire-less transmitting unit 6 of the micro controller 33 as shown in FIG. 5. It is noted that the power unit 9 can be other type of batteries such self-generating batteries. When the adaptor plug is electrically between the wall socket 20 and the electronic device 10, the city power supplies electric power to the micro controller 33, and the operation of the micro controller 33 activates the power unit 9 which generates power and stores the power.

By providing the latest status of the electrical connection between the electronic device 10 and the wall socket 20 to the mobile device 1 of the user, the user can monitor and avoid potential risks to the electronic device 10.

While we have shown and described the embodiment in accordance with the present invention, it should be clear to those skilled in the art that further embodiments may be made without departing from the scope of the present invention.

1. An adaptor plug assembly for being connected between an electronic device and a wall socket, and comprising:
a mobile device having a receiving unit;
an adaptor plug laving a housing which includes a first connection end and a second connection end;
two terminals each having a first end thereof extending through the first connection end, and a second end of each of the two terminals connected to the second connection end, a coil mounted to one of the two terminals and electrically connected to a micro controller, the micro controller comprising a calculating t nit, a transforming unit and a wire-less transmitting unit, the transforming unit receiving current inducted by the coil and transforming the current into a first signal which is sent to the calculating unit, the calculating unit calculating the first signal and obtaining a second signal, the wire-less transmitting unit transmitting the second signal to the receiving unit of the mobile device, and
a power unit installed in the housing and electrically connected to the micro controller, the power unit providing power to the micro controller, such that a user monitors electrical connection bet seen the wall socket and electronic device by the mobile device.

2. The adaptor plug assembly as claimed in claim 1, wherein the micro controller includes an overload protection unit which checks the inducted current of the coil and depresses voltage to protect the micro controller when the overload current is detected.

3. The adaptor plug assembly as claimed in claim 1, wherein the power unit is chargeable batteries, when the terminals on the first connection end are plugged to the wall socket, the power unit is charged, when the electronic device is connected to the second connection end, the power unit outputs power to the micro controller.

4. The adaptor plug assembly as claimed in claim 2, wherein the power unit is chargeable batteries, when the terminals on the first connection end are plugged to the wall socket, the power unit is charged, when the electronic device is connected to the second connection end, the power unit outputs power to the micro controller.

5. The adaptor plug assembly as claimed in claim 1, wherein the terminals each are a rod or a plate, the second connection end includes three receptacle holes, the two respective second ends of the two terminals are connected to two of the three receptacle holes, the other one of the three receptacle holes has an earth terminal located therein.

6. The adaptor plug assembly as claimed in claim 5, wherein a transmitting method between the wire-less transmitting unit of the micro controller and the receiving unit of the mobile device is made by way of low-power Bluetooth transmission, cloud-transmission or Ultra-red transmission.
